(19) United States
(12) Patent Application Publication
(10) Pub. No.: US 2010/0238779 A1
(43) Pub. Date: Sep. 23, 2010

(54) DEVICE AND METHOD FOR DETERMINING DEFECT SECTOR ON OPTICAL DISC

(76) Inventors: Shih-Kuo Chen, Taoyuan County (TW); Chin-Fa Hsu, Taoyuan County (TW); Shiu-Ming Chu, Taoyuan County (TW)

Correspondence Address: NORTH AMERICA INTELLECTUAL PROPERTY CORPORATION, P.O. BOX 506, MERRIFIELD, VA, 22116, US

(21) Appl. No.: 12/687,138

(22) Filed: Jan. 14, 2010

(30) Foreign Application Priority Data
Mar. 17, 2009 (TW) 098108707

(51) Int. Cl. G11B 20/18; G11C 29/04; G06F 11/10

(52) U.S. Cl. 369/53.42; G9B/20.046; 714/763; 714/824; 714/704; 714/E11.034

(57) ABSTRACT

A device and method for determining defect sectors on an optical disc receives writing commands and data by a processor, and saves the writing data in a memory. An error correction code (ECC) encodes the writing data into encoded digital signals, and the encoded digital signals form modulated digital signals by a modulation device which are saved back into the storage. The processor controls a pick-up head to write and read the modulated digital signals. A comparing unit generates a number of errors by comparing the modulated digital signals before and after writing. The defect sector is directly determined if the number of errors are low or high. The modulated digital signal is decoded to determine the defect sector based on the failure or success of decoding if the number of errors lie in the middle of the range.

### BACKGROUND OF THE INVENTION

1. Field of the Invention

The present invention relates to an apparatus and a method for determining defect sectors on an optical disc, and more particularly, to an apparatus and method for verifying written data as correct or not when an optical disc repeatedly writes data.

2. Description of the Prior Art

Optical discs usually suffer from the effects of slight stains, dust, limits in manufacturing quality, ingredient degradation and scratches, leading to damage of data marks in partial areas, thus resulting in defect sectors. If data are written in these defect sectors, they usually cannot be read correctly. Therefore, the reading processes of optical discs must provide defect management mechanisms to backup and register addresses of defect sectors in order to prevent damage to stored data.

FIG. 1 is a flowchart of an optical disc defect sector determining method according to a prior art, R.O.C. Patent, No. 1302300. Firstly, in step P1, data marks written in the optical disc are read. In step P2, an error correction code (ECC) is utilized to perform data mark decoding. Next in step P3, it is checked whether there is a decoding error. If there is no decoding error, the flow goes to step P4 to determine the data sector as a non-defect sector. If there is a decoding error, the flow goes to step P5 to utilize ECC to correct the decoding error. In step P6, it is checked whether the decoding error correction is successful or not. If the decoding error correction is successful, the flow goes to step P4 to determine the data sector as a non-defect sector. If the decoding error correction fails, the flow goes to step P7 to determine the data sector as a defect sector, and the defect management system writes the address of the defect sector in the storage.

The aforementioned technique determines locations of defect sectors in advance to prevent writing data in the defect sectors. However, regardless of an extent of damage, the prior art performs correction equally for data sectors with decoding errors to determine defect sectors. Since decoding error correction consumes a lot of time, an execution performance of the optical disc drive will be significantly degraded. Another prior art, R.O.C. Patent No. 200638413, discloses a method of determining defect sectors according to a number of errors of ECC decoding. Utilizing setting a threshold, a data sector is determined as a non-defect sector when the number of errors is lower than the threshold, and the data sector is determined as a defect sector when the number of errors is higher than the threshold, therefore a correction time is saved and a performance of the optical disc drive is improved.

However, the threshold of the method of determining defect sectors is hard to set accurately. A low threshold will lead to too many defect sectors, thereby not only reducing effective storage volume of the optical disc but also requiring rewriting of the data, leading to an elongated writing time. A high threshold will lead to a greater probability of writing data in defect sectors, so stored data cannot be read. In addition, the aforementioned prior art also requires decoding via ECC to determine defect sectors according to the number of errors, which not only elongates writing time, but also means that the errors of ECC decoding may refer to an error of decoding format instead of data mark reading errors, so the number of errors cannot directly indicate an extent of defect. Therefore, there are still problems in the processing of the conventional methods of determining defect sectors on an optical disc.

### SUMMARY OF THE INVENTION

One of the objectives of the present invention is to provide an apparatus of determining defect sectors on an optical disc, which sets a number of errors generated from a comparator by comparing regenerated modulated digital signals and original modulated digital signals, as a reference for determining defect sectors to thereby enhance writing performance.

Another objective of the present invention is to provide a method of determining defect sectors on an optical disc, which compares modulated digital signals before and after decoding as well as writing to derive a status of defect sectors, and thereby facilitates determination of defect sectors.

Yet another objective of the present invention is to provide a method of determining defect sectors on an optical disc, which categorizes a number of errors into three categories: high number of errors, medium number of errors and low number of errors, wherein for a high number of errors, the data sector is determined as a defect sector directly, for a low number of errors, the data sector is determined as a non-defect sector, and for a medium number of errors, a decoding correction is performed, and a decoding result is utilized for determining defect sectors to enhance an accuracy of determination.

To achieve the aforementioned objectives, the apparatus of determining defect sectors on an optical disc of the present invention receives writing data and commands from a processor, and stores writing data in a storage medium. The apparatus converts the writing data into modulated digital signals via ECC, and modulated digital signals are converted into original modulated digital data via a modulation apparatus and stored in the storage. The processor controls a pick-up head to write or read modulated digital signals, and a comparator is utilized to derive a number of errors, which is utilized to determine defect sectors.

A method of determining defect sectors on an optical disc of the present invention is provided, including: reading data sectors of written data to form regenerated modulated digital signals; comparing the regenerated modulated digital signals with original modulated digital signals to derive a number of errors according to differences between the regenerated modulated digital signals and the original modulated digital signals; checking the number of errors is a low number of errors, medium number of errors or high number of errors, wherein if the number of errors is a high number of errors or a low number of errors, determining a defect sector status according to a predetermined setting, if the number of errors is a medium number of errors, performing decoding and determining the defect sector status according to a successful decoding.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a flowchart of an optical disc defect sector determining method according to a prior art.

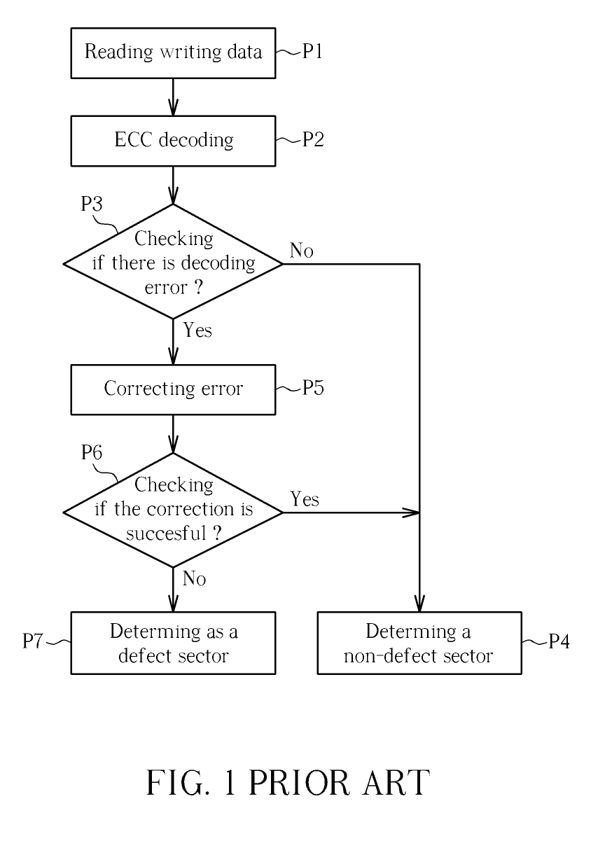

FIG. 2 is a block diagram of an optical disc drive utilizing an apparatus of determining defect sectors according to an embodiment of the present invention.

FIG. 3 is a flowchart of a method of determining defect sectors on an optical disc according to a first embodiment of the present invention.

FIG. 4 is a flowchart of a method of determining defect sectors on an optical disc according to a second embodiment of the present invention.

### DETAILED DESCRIPTION

To illustrate the adopted techniques and effect of this invention described in the aforementioned statement, abetter actual example along with figures and detailed description is demonstrated below.

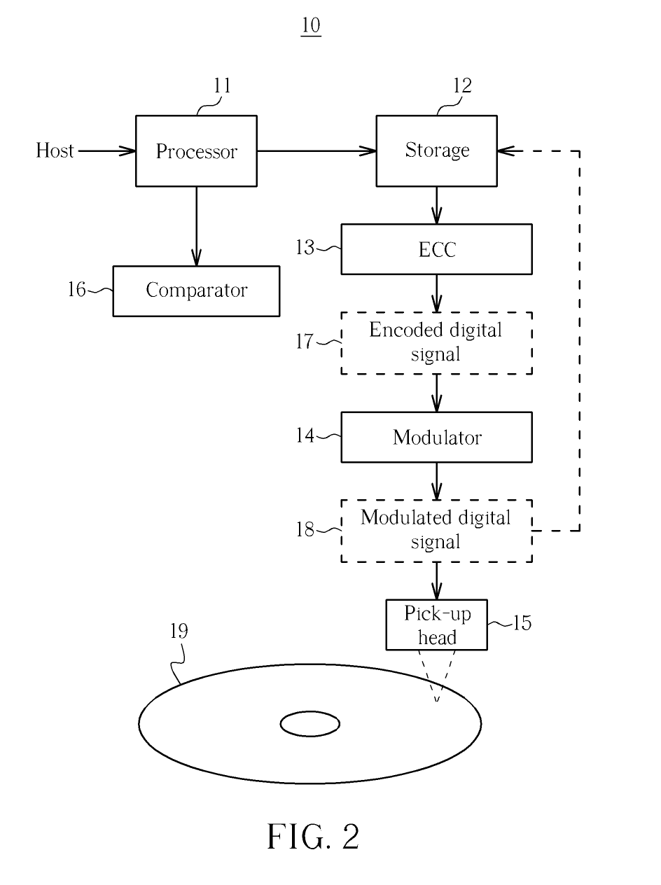

Please refer to FIG. 2, which is a block diagram of an optical disc drive 10 utilizing an apparatus of determining defect sectors according to an embodiment of the present invention. The optical disc drive 10 includes a processor 11, a storage 12, an error correction code (ECC) 13, a modulator 14, a pick-up head 15 and a comparator 16. The processor 11 receives writing data and commands from a host and stores writing data in the storage 12. The ECC 13 is utilized to encode the writing data to form encoded digital signals 17 of a specific format of ECC 13. Next, the modulator 14, e.g., an eight-fourteen modulation (EFM), is utilized to mix encoded digital signals 17 stored temporarily with a specific code to form longer modulated digital signals 18, and modulated digital signals 18 are stored in the storage 12 as the original modulated digital signals 18. Then the pick-up head 15 reads the original modulated digital signals 18 in the storage 12 and utilizes 3T-11T data marks of different unit time length to form a plurality of unit data sectors and write them in the optical disc 19.

When verifying that the data is read correctly or not, the processor 11 controls the pick-up head 15 to read data marks on the optical disc to form regenerated modulated digital signals 18 which are thereby stored temporarily in the storage 12. Before the regenerated modulated digital signals 18 are decoded by the ECC 13, the apparatus of determining defect sectors on an optical disc of the present invention utilizes the comparator 16 to compare the regenerated modulated digital signals with the original modulated digital signals stored in the storage 12 (with a unit of data sectors). Setting the original modulated digital signals as comparing references, each one of the regenerated modulated digital signals which does not comply with the original modulated digital signals is regarded as an error and the number are accumulated to derive a number of errors of the regenerated modulated digital signals in each data sector. Since the number of errors directly indicates a degree of writing failure, the number of errors of each data sector indicates a quality of the data sector on the optical disc 19. Therefore, the processor 11 of the present invention sets the number of errors of the modulated digital signals 18 before and after writing as an indication of whether the data sector is defect or not.

Therefore, via the number of errors, the apparatus of determining defect sectors on an optical disc of the present invention utilizes the comparator to compare the regenerated modulated digital signals, which are read from data marks directly, with the original modulated digital signals stored before writing to derive a number of errors of inconsistency quickly without utilizing ECC to determine defect sectors, leading to a performance enhancement of the optical disc drive.

The method of determining defect sectors on an optical disc of the present invention is to categorize a number of errors, which are derived from comparing the regenerated modulated digital signals 18 with the original modulated digital signals, into three categories: high number of errors, medium number of errors and low number of errors, indicating severe, medium, and slight extent of damage in the data sector, respectively. For a data sector with a high number of errors, i.e., a sector of severe data mark damage, the data within cannot be read or consumes a lot of decoding time due to a large amount of errors thus usually resulting in failure in ECC decoding, so this data sector is determined directly as a defect sector and therefore a sector for which the ECC is no longer performed. For a data sector with a low number of errors, i.e., a sector of slight data mark damage, the data within can be read via successful ECC decoding due to a small amount of errors, and therefore the data sector is determined as a non-defect data sector and a sector for which the ECC is no longer required.

As for a data sector with a medium number of errors, most of these sectors are intermingled with data sectors that can be decoded successfully or data sectors that will fail to be decoded. If all of the data sectors are categorized as defect sectors, a storage volume of the optical disc is reduced, and if all of the data sectors are categorized as non-defect sectors, certain data cannot be read afterwards. The method of determining defect sectors on an optical disc of the present invention is to perform ECC decoding for the data sectors with a medium number of errors and determine the data sector as a defect sector or not according to the ECC decoding result. In this way, the data sector with a medium number of errors can be prevented from being determined incorrectly.

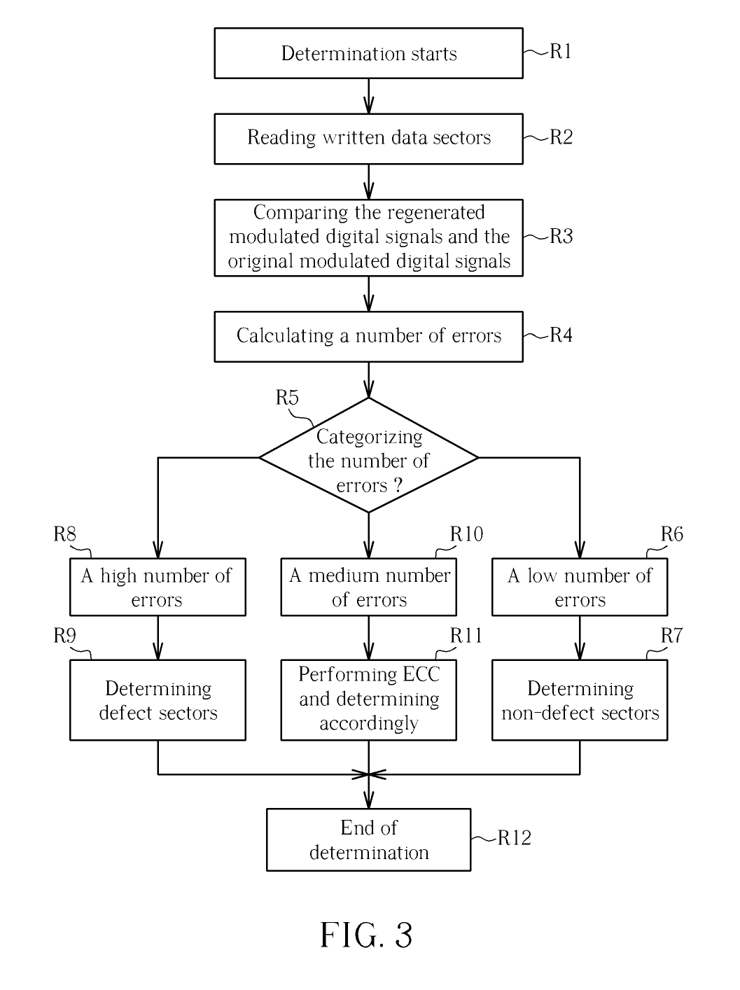

FIG. 3 is a flowchart of a method of determining defect sectors on an optical disc according to a first embodiment of the present invention. The steps of determining the writing data sector on an optical disc as a defect sector are described as follows: firstly, in step R1, determination of a defect sector is started. In step R2, written data sectors on the optical disc are read to form regenerated modulated digital signals. In step R3, the regenerated modulated digital signals and the original modulated digital signals are compared. In step R4, the original modulated digital signals are used as references to check incompliant regenerated modulated digital signals to form error signals and calculate a number of errors. Next, in step R5, the number of errors is categorized into a lower number of errors, a medium number of errors and a high number of errors.

Data sectors that are slightly damaged are categorized as a low number of errors in step R6. Then in step R7, the data sectors are determined as non-defect sectors directly, and no ECC is performed. Data sectors that are severely damaged are categorized as a high number of errors in step R8. Then in step R9, the data sectors are determined as defect sectors directly, and no ECC is performed. Data sectors that have medium damage are categorized as a medium number of errors in step R10. Then in step R11, the ECC is performed directly, wherein a defect sector status is determined according to whether the decoding result is a success or a failure. After the determinations in steps R7, R9 or R11 are completed, the process proceeds to step R12, wherein the determination stage ends.

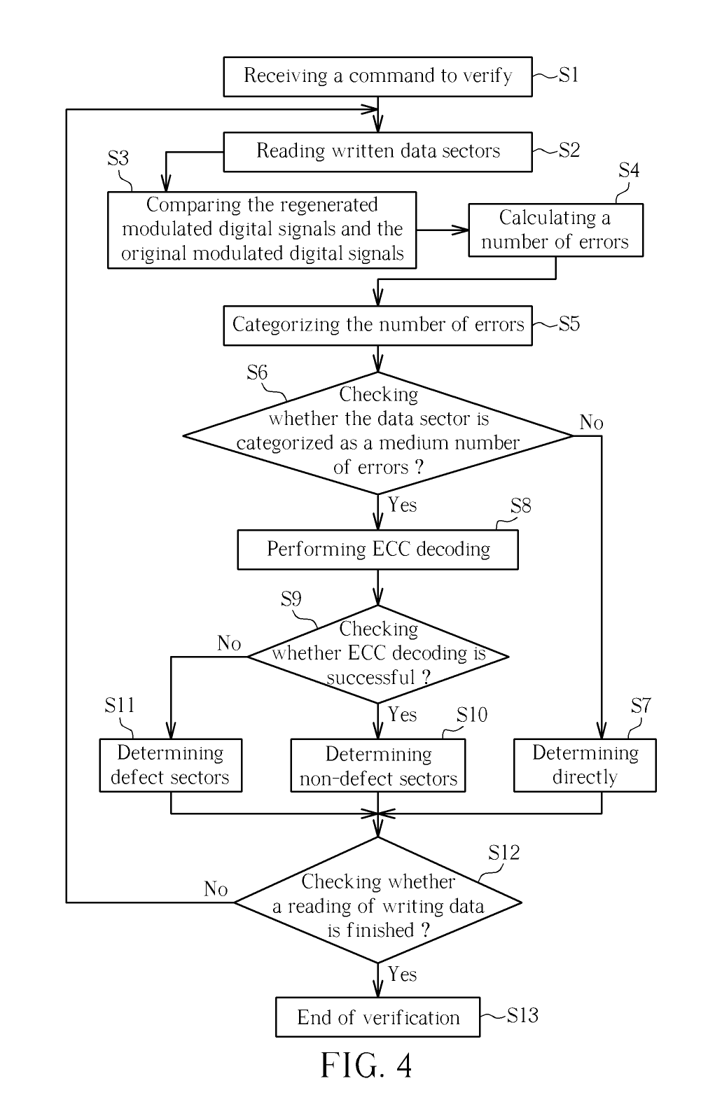

FIG. 4 is a flowchart of a method of determining defect sectors on an optical disc according to a second embodiment of the present invention. This embodiment is a process of implementing the present invention to verify whether data written into a data sector is correct or not, and the detailed steps are described as follows: firstly, in step S1, the optical disc drive receives a command from a host to verify whether data are written correctly or not. In step S2, the writing data sector of the verification is read to form regenerated modulated digital signals. Next, in step S3, the regenerated modulated digital signals are compared with the original modulated digital signals. In step S4, the original modulated digital signals are used as references to check incompliant regenerated modulated digital signals to form error signals and calculate a number of errors. Next in step S5, the number of errors is categorized into a lower number of errors, a medium number of errors and a high number of errors.

Then, in step S6, it is checked whether the data sector is categorized as a medium number of errors in step S5. If the data sector is not categorized as a medium number of errors, the process goes to step S7 and no ECC is performed. A defect sector status is determined according to the categorization of the number of errors, i.e., a data sector with a high number of errors is determined as a defect sector and a data sector with a low number of errors is determined as a non-defect sector. If the data sector is categorized as a medium number of errors, the process goes to step S8, and ECC decoding is performed for the data sector with a medium number of errors. The process then goes to step S9 to check if the decoding is successful or not. If the encoding is successful, the process goes to step S10 to determine the data sector as a non-defect sector, and if the encoding fails, the process goes to step S11 to determine the data sector is a defect sector. When determinations in steps S7, S10 or S11 are completed, the process goes to step S12 to check whether a reading of the writing data of verification is finished or not. If the reading is not finished, the process goes to step S2 to continue reading writing data, and if the reading is finished, the process goes to step S13 to end the writing verification.

As a result, the method of determining defect sectors on an optical disc of the present invention utilizes undecoded modulated digital signals before and after writing for comparison to derive a number of errors indicating an extent of damage and facilitate determining of defect sectors. Via categorizing the number of errors into three categorizations, a data sector with a high number of errors is determined as a defect sector directly, the data sector with a low number of errors is determined as a non-defect sector directly, and a data sector with a medium number of errors, time-consuming decoding is performed, and via a successful or failed decoding result, the defect sectors are determined correctly, leading to the objective of enhancing determination accuracy.

Those skilled in the art will readily observe that numerous modifications and alterations of the device and method may be made while retaining the teachings of the invention.

What is claimed is:

1. An apparatus of determining defect sectors on an optical disc, comprising:
a processor, for receiving writing data and writing commands;
a storage, for storing the writing data;
an error correction code (ECC), for encoding the writing data into encoded digital signals of specific formats;
a modulator, for converting the encoded digital data into original modulated digital signals and storing the original modulated digital signals in the storage;
a pick-up head, controlled by the processor, for writing the original modulated digital signals as data marks in a data sector, or reading the data marks as regenerated modulated digital signals; and
a comparator, for comparing the regenerated modulated digital signals with the original modulated digital signals in the data sector to derive a number of errors;
wherein the processor determines whether the data sector is a defect sector according to the number of errors generated from the comparator.

2. The apparatus of claim 1, wherein the encoded digital signals are stored temporarily in the storage.

3. The apparatus of claim 1, wherein the regenerated modulated digital signals being read are stored temporarily in the storage.

4. The apparatus of claim 1, wherein the modulator is an Eight-to-fourteen modulation (EFM) apparatus.

5. A method of determining defect sectors on an optical disc, comprising:
(1) reading original modulated digital signals in a data sector to form regenerated modulated digital signals;
(2) comparing the regenerated modulated digital signals and the original modulated digital signals in the data sector to derive a number of errors according to a number of differences between the regenerated modulated digital signals and the original modulated digital signals;
(3) checking the number of errors is a low number of errors, medium number of errors or high number of errors, and if the number of errors is a medium number of errors, performing a decoding and determining the defect sector status according to a failure of the decoding.

6. The method of claim 5, wherein the step (3) comprises determining the data sector is a non-defect sector if the number of errors is a low number of errors, and determining the data sector is a defect sector if the number of errors is a high number of errors.

7. The method of claim 5, wherein the step (3) comprises checking the decoding is successful or not, if the decoding is successful, determining the data sector is the non-defect sector; otherwise, determining the data sector is the defect sector.

8. The method of claim 5, wherein the decoding performed in the step (4) is an error correction code (ECC) decoding.

9. The method of claim 5, wherein the determining method is for verifying whether writing data in the data sector is written correctly or not.
